(19) United States
(12) Patent Application Publication
(10) Pub. No.: US 2018/0172472 A1
(43) Pub. Date: Jun. 21, 2018

(54) EXPLOSION PROOF PIEZOELECTRIC ULTRASONIC DETECTOR

(71) Applicant: Honeywell International Inc., Morris Plains, NJ (US)

(72) Inventors: Michael Grant, Wareham (GB); Jeffrey Cutler, Poersmouth (GB); Rodney Royston Watts, Wimborne (GB)

(21) Appl. No.: 15/850,043

(22) Filed: Dec. 21, 2017

Related U.S. Application Data
(60) Provisional application No. 62/437,382, filed on Dec. 21, 2016.

(51) Int. Cl. G01D 3/08; B06B 1/06; H01L 41/053; H01L 41/047; H01L 41/113; H01L 41/23; H01L 41/313; H01L 41/29; G01M 3/24; G01H 11/08

(52) U.S. Cl. CPC G01D 3/08; B06B 1/0666; H01L 41/0533; H01L 41/0475; G01H 11/08; H01L 41/23; H01L 41/313; H01L 41/29; G01M 3/243; H01L 41/1132

(57) ABSTRACT

Embodiments relate generally to an explosion proof ultrasonic detector. The explosion proof ultrasonic detector comprises a metal enclosure configured to face ultrasound pressure waves, a sense element, wherein the sense element is attached to the metal enclosure via solder, a compression element configured to contact the sense element, and a printed circuit board configured to compress the compression element and to connect electrically to the sense element.

### CROSS-REFERENCE TO RELATED APPLICATIONS

The present application claims priority to U.S. Provisional Patent Application Ser. No. 62/437,382, filed Dec. 21, 2016 by Michael Grant, et al. and entitled “Explosion Proof Piezoelectric Ultrasonic Detector” which is incorporated herein by reference as if reproduced in its entirety.

### STATEMENT REGARDING FEDERALLY SPONSORED RESEARCH OR DEVELOPMENT

Not applicable.

### REFERENCE TO A MICROFICHE APPENDIX

Not applicable.

### BACKGROUND

Explosion proof devices may be used in hazardous environments such as a gas pipeline, a hydrocarbon well site, a gas pipeline compression station, a chemical refinery and other environments that may be subject to explosions. For example, leakage of a pressurized gas may unintentionally occur when bad pipe joints leak or pipes are damaged, for example due to hitting the pipe accidently with metal equipment. An ignition of a leaking gas may be triggered by a spark or other event. Depending on circumstances, the ignition of a leaking gas may be accompanied by an initial explosion which produces very high transient pressures.

### SUMMARY

In an embodiment, an explosion proof ultrasonic detector is disclosed. The explosion proof ultrasonic detector comprises a metal enclosure configured to face ultrasound pressure waves, a sense element, wherein the sense element is attached to the metal enclosure via solder, a compression element configured to contact the sense element, and a printed circuit board configured to compress the compression element and to connect electrically to the sense element.

In an embodiment, a method for assembling an explosion proof ultrasonic detector is disclosed. The method comprises soldering a first surface of a sense element to an inner surface of a metal enclosure, applying compression to a second surface of the sense element, wherein the second surface is opposite the first surface, maintaining the compression to the second surface of the sense element via a compression element, and attaching a printed circuit board to the metal enclosure, wherein the printed circuit board contacts the compression element.

### BRIEF DESCRIPTION OF THE DRAWINGS

For a more complete understanding of the present disclosure, reference is now made to the following brief description, taken in connection with the accompanying drawings and detailed description, wherein like reference numerals represent like parts.

FIG. 1 is an illustration of an explosion proof ultrasonic detector according to an embodiment of the disclosure.

FIG. 2 is an exploded view of some parts of an explosion proof ultrasonic detector according to an embodiment of the disclosure.

FIG. 3 is an illustration of another explosion proof ultrasonic detector according to an embodiment of the disclosure.

FIG. 4 is an illustration of yet another explosion proof ultrasonic detector according to an embodiment of the disclosure.

### DETAILED DESCRIPTION

It should be understood at the outset that although illustrative implementations of one or more embodiments are illustrated below, the disclosed systems and methods may be implemented using any number of techniques, whether currently known or not yet in existence. The disclosure should in no way be limited to the illustrative implementations, drawings, and techniques illustrated below, but may be modified within the scope of the appended claims along with their full scope of equivalents.

The following brief definition of terms shall apply throughout the application:

The term “comprising” means including but not limited to, and should be interpreted in the manner it is typically used in the patent context;

The phrases “in one embodiment,” “according to one embodiment,” and the like generally mean that the particular feature, structure, or characteristic following the phrase may be included in at least one embodiment of the present invention, and may be included in more than one embodiment of the present invention (importantly, such phrases do not necessarily refer to the same embodiment);

If the specification describes something as “exemplary” or an “example,” it should be understood that refers to a non-exclusive example;

The terms “about” or “approximately” or the like, when used with a number, may mean that specific number, or alternatively, a range in proximity to the specific number, as understood by persons of skill in the art field; and

If the specification states a component or feature “may,” “can,” “could,” “should,” “would,” “preferably,” “possibly,” “typically,” “optionally,” “for example,” “often,” or “might” (or other such language) be included or have a characteristic, that particular component or feature is not required to be included or to have the characteristic. Such component or feature may be optionally included in some embodiments, or it may be excluded.

Embodiments of the disclosure include methods and systems for providing an explosion proof piezoelectric sensor. Unintentional leakage of gas from pressurized installations, which may be caused by failed pipe joints, or a pipe fracture, needs to be detected as quickly as possible, as the leaking gas might be dangerous for the environment or may lead to severe product losses. Once a leak is detected, it may be indicated to a monitor or supervisor, so the leak may be contained or otherwise mitigated. Due to the nature of gas leaks, detection instruments may be required to be explosion proof, so that detection may continue even if an explosion occurs near the instrument, and/or so that an explosion initiated within the instrument does not propagate to an external environment.

A gas leakage from a pressurized source may produce sound, which typically has frequencies in the audible and ultrasonic ranges. An ultrasonic detector may be configured to detect ultrasound frequencies generated by a gas leak, and therefore, detect the gas leak. The ultrasonic detector may signal the level of the detected ultrasound, and may be configured to activate an alarm if the detected ultrasound level is above a certain threshold.

Embodiments of the disclosure relate to explosion proof ultrasonic detectors, which may comprise one or more piezoelectric element encapsulated in a metal enclosure, where the piezoelectric element may convert the pressure of sound waves from mechanical energy into an electric signal.

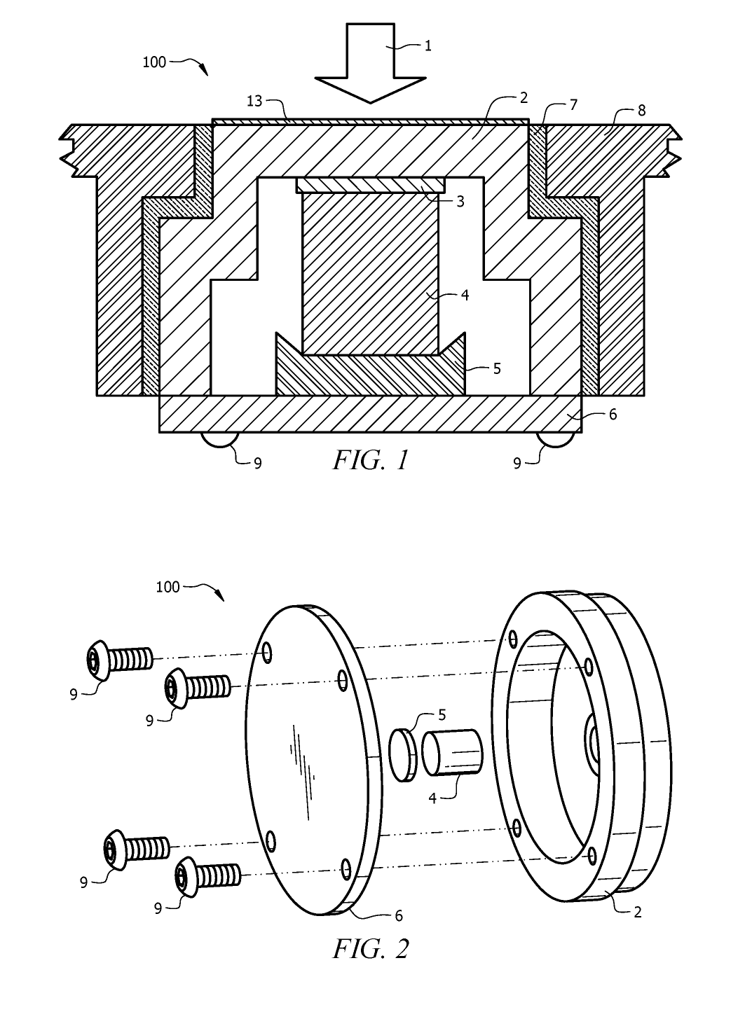

FIG. 1 illustrates an explosion proof ultrasonic detector 100, where arrow 1 illustrates ultrasound pressure waves coming from the environment. The explosion proof ultrasonic detector 100 may comprise a metal enclosure 2 facing the ultrasound pressure waves, where the metal enclosure 2 may function as one of the electrodes of a sense element 4 (which may be a piezoelectric sense element, or may also be known as a piezo sense element). The sense element 4 may be attached to the metal enclosure 2 via solder 3. The sense element 4 may also comprise one or more electrodes, which may be silver electrodes. Additionally, the sense element 4 may be in contact with an electrically conductive compression element 5 and a printed circuit board (PCB) 6. The PCB 6 may be configured to compress the electrically conductive compression element 5 and to connect electrically to an electrode of the sense element 4. The explosion proof ultrasonic detector 100 may also comprise an instrument enclosure 8 that may be sealed to the metal enclosure 2 via a layer of sealing material 7.

As shown in FIG. 1, the sense element 4 may be soldered directly to the metal enclosure 2, and the metal enclosure 2 may be directly attached to the PCB 6 via screws 9. The metal enclosure 2 may function as an electrode by directly contacting the PCB 6 and connecting the sense element 4 to the PCB 6. The electrically conductive compression element 5 may provide explosion protection to the sense element 4, and possibly the other elements of the explosion proof ultrasonic detector 100. The electrically conductive compression element 5 may further provide adaptation of fit of parts in the context of dimensional variation within tolerance limits of manufactured parts. When the explosion proof ultrasonic detector 100 is assembled, the sense element 4 may be under compression between the metal enclosure 2 (and solder 3) and the PCB 6, via the electrically conductive compression element 5. This compression may reduce the risk of separation between the sense element 4 and the electrodes and/or PCB 6, which could occur due to strong mechanical shock, vibration, thermal shock, and/or excessive piezo resonance. Use of the electrically conductive compression element 5 between the sense element 4 and the PCB 6 allows the compression of the sense element 4 to be maintained over a large temperature range without damaging the explosion proof ultrasonic detector 100 assembly, where the elasticity of the electrically conductive compression element 5 may be configured to distribute compressive force evenly. The solder 3 may be resistant to very wide temperature ranges and thermal cycling, and may be able to withstand shock and impact without the solder 3 joint failing. The solder 3 may also provide a reliable electrical contact between the sense element 4 and the PCB 6 via the metal enclosure 2.

The surface of the metal enclosure 2 attached to the sense element 4 may function as a membrane to transfer ultrasound pressure waves 1 from the external environment to the sense element 4 while also protecting the sense element 4 from the force of an explosive blast. The sealing material 7 may provide a water-tight seal with the metal enclosure 2, protecting the sense element 4, the electrically conductive compression element 5, and the PCB 6. The sealing material 7 may provide electrical isolation between the metal enclosure 2 and the instrument enclosure 8. The sealing material 7 may also provide isolation (i.e., sound insulation) to prevent the propagation of ultrasonic signals from the instrument enclosure 8 into the sense element 4 and/or the metal enclosure 2. Ultrasonic signals may originate in the instrument enclosure 8 as a consequence of impact or vibration. In an embodiment, the sealing material 7 may comprise silicone. In an embodiment, the sealing material 7 may be provided as a pre-molded part, for example a pre-molded silicone part. In an embodiment, the sealing material 7 may have a length or height of about 15.9 mm. In an embodiment, the sealing material 7 may have a length or height that is sufficient to resist explosions up to a predefined maximum strength.

The sense element 4 may operate in a Faraday cage, being surrounded by metal surfaces via the metal enclosure 2 and PCB 6. Said in another way, the metal enclosure 2 and the PCB 6 may form a Faraday cage that encloses the sense element 4. In an embodiment, the Faraday cage formed by the metal enclosure 2 and the PCB 6 may further enclose some electronic devices installed on the PCB 6. The PCB 6 may comprise a continuous metal layer which may contact the metal enclosure 2 of the explosion proof ultrasonic detector 100. This configuration may minimize the influence of electromagnetic interference (EMI), provide electromagnetic compatibility, and may allow the explosion proof ultrasonic detector 100 to achieve high signal to noise ratio (SNR) performance.

A front face of the metal enclosure 2, which faces incoming ultrasound pressure waves 1, may comprise a coating 13, which may comprise a polymer such as Polytetrafluoroethylene (PTFE), another similar material, or a plastic label. The coating 13 may function as a protective cover for the metal enclosure 2 resistant to many aggressive chemicals, may function in a broad temperature range, and may not compromise the acoustic properties of the metal enclosure 2, allowing ultrasound waves to pass through. In an embodiment, the coating 13 may improve the acoustic transfer of energy from the ultrasound pressure waves 1 to the metal enclosure 2 and/or to the sense element 4.

The explosion proof ultrasonic detector 100 described in FIG. 1 may comprise very few components which promote simple assembly optimized for manufacturing. Typical ultrasound detection products may not comprise explosion proof elements. An explosion proof, highly reliable, ultrasonic sense element (which may comprise a microphone) may be preferred for detecting gas leaks through airborne ultrasound pressure waves, especially in an environment where harmful substances, such as H₂S, may be present.

FIG. 2 illustrates an exploded view of the explosion proof ultrasonic detector 100, comprising the metal enclosure 2, one or more piezoelectric sense element 4, electrically conductive compression element 5, PCB 6, and screws 9 for assembly. In an embodiment, the electrically conductive compression element 5 may comprise rubber material. Note that FIG. 2 does not depict the presence of solder 3 which may not be provided until final assembly or manufacturing of the explosion proof ultrasonic detector 100. Said in other words, the solder 3 may be considered to be separate from a part of the kit for assembling and manufacturing the explosion proof ultrasonic detector 100 and may be provided during the manufacturing process as a consumable tool or consumable material.

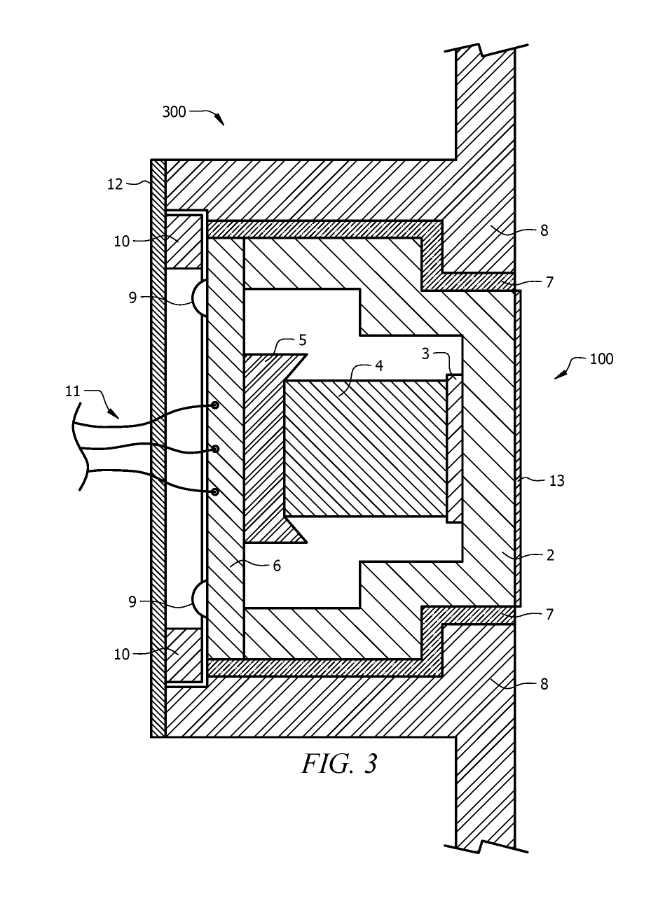

FIG. 3 illustrates an explosion proof ultrasonic detector 100 attached to an exemplary instrument 300. As an example, the exemplary instrument 300 may be required to survive at least 600 psi pressure from outside toward the instrument and/or from the interior of the instrument toward environment. Alternatively, the exemplary instrument 300 and the explosion proof ultrasonic detector 100 may be required to survive other predefined pressures. The explosion proof ultrasonic detector 100 installed in the instrument 300 may be secured from the interior of the instrument 300 with a locking ring 10, or another similar mechanical element. In some embodiments, the explosion proof ultrasonic detector 100 may be separated from the interior of the instrument 300, such as via a layer of sealant 12. The sealant 12 may comprise silicone. One or more leads 11 from the PCB 6 may extend into the interior of the instrument 300 through the locking ring 10 and/or sealant 12.

Soldering of the sense element 4 to the metal enclosure 2 may be completed with a solder 3 having a low melting temperature that is lower than the Curie temperature of the material of the sense element 4, thereby preventing any sensitivity loss for the sense element 4. As an example, the Curie temperature of the sense element 4 may be approximately 300° C. The coating 13 (which may comprise PTFE) on the metal enclosure 2 may prevent bimetallic corrosion between the metal enclosure 2 of the ultrasonic sensor and the instrument enclosure 8, as these may be made from different metals.

Embodiments of the disclosure may include a method of assembling an explosion proof ultrasonic detector 100. The sense element 4 may be soldered directly to the metal enclosure 2. Compression may be applied to the sense element 4 via the electrically conductive compression element 5, wherein a consistent pressure is applied to the solder 3 material, improving the reliability of that connection. The PCB 6 may then be attached to the metal enclosure 2 via screws 9, wherein the PCB 6 may contact and maintain the compression from the electrically conductive compression element 5.

The metal enclosure 2 may be sealed to the instrument enclosure 8 via sealing material 7. Additionally, the coating 13 may be applied to the front face of the metal enclosure 2, wherein the coating 13 may reduce corrosion from exposure to harmful chemicals, and may improve ultrasound transmission through the metal enclosure 2.

In some embodiments, a locking ring 10 may be attached to the metal enclosure to further retain the metal enclosure within the instrument enclosure. In some embodiments, a layer of sealant 12 may be applied over the metal enclosure 2 to separate the metal enclosure and the other elements from the interior of the instrument enclosure 8.

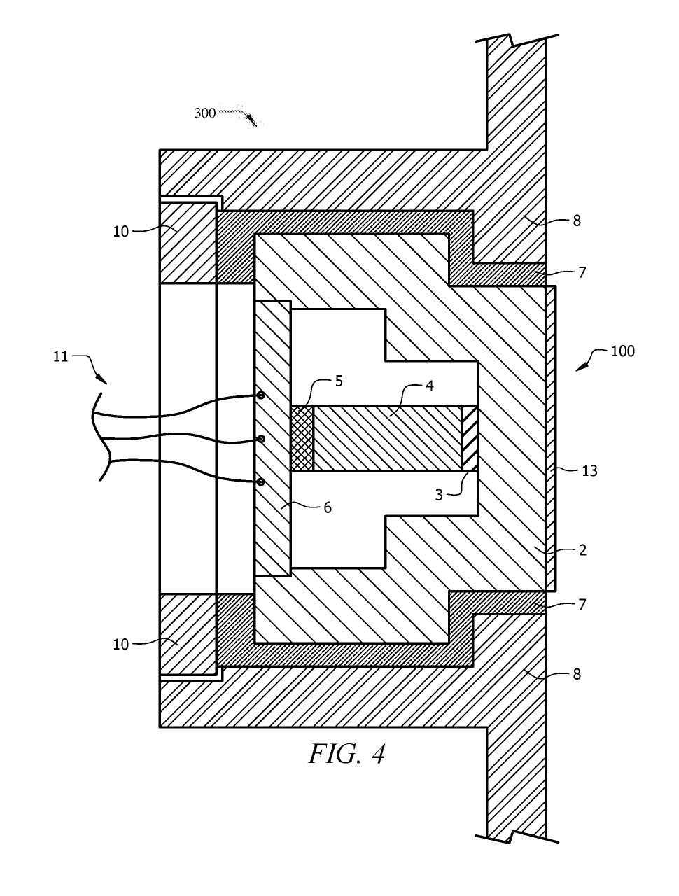

FIG. 4 illustrates an explosion proof ultrasonic detector 100 attached to an exemplary instrument 300. The explosion proof ultrasonic detector 100 attached to the exemplary instrument 300 is in all respects similar to the embodiments described above with reference to FIG. 1 and FIG. 3, with the exception that in the embodiment illustrated in FIG. 4 the instrument enclosure 8 has been extended so there is an offset between a leftwards facing surface of the metal enclosure 2 and a rightwards facing surface of the locking ring 10, the sealing material 7 has been extended to contact the edge of the locking ring 10, and the sealing material 7 extends between the metal enclosure 2 and the locking ring 10 (i.e., between a leftwards facing surface of the metal enclosure 2 and a rightwards facing surface of the locking ring 10). The extension of the sealing material 7 between the metal enclosure 2 and the locking ring 10 may provide additional electrical insulation and/or isolation of the explosion proof ultrasonic detector 100 from the instrument enclosure 8, additional mechanical buffering of the explosion proof ultrasonic detector 100 in the event of explosion, and additional sound insulation and/or isolation of the explosion proof ultrasonic detector 100 from the instrument enclosure 8. In an embodiment, the sealing material 7 may have a length or height of about 15.9 mm. In an embodiment, the sealing material 7 may have a length or height that is sufficient to resist explosions up to a predefined maximum strength.

Embodiments of the disclosure may comprise a method for protecting an ultrasonic detector from an explosion. Compression may be applied to a sense element of the ultrasonic detector via a compression element. Shocks, vibrations, and other mechanical forces that affect the ultrasonic detector may be absorbed by the compression element.

In a first embodiment, an explosion proof ultrasonic detector may comprise a metal enclosure configured to face ultrasound pressure waves; a sense element, wherein the sense element is attached to the metal enclosure via solder; a compression element configured to contact the sense element; and a PCB configured to compress the compression element and to connect electrically to the sense element.

A second embodiment may include the explosion proof ultrasonic detector of the first embodiment, wherein the sense element comprises one or more electrodes.

A third embodiment may include the explosion proof ultrasonic detector of the second embodiment, wherein the metal enclosure functions as an electrode of the sense element.

A fourth embodiment may include the explosion proof ultrasonic detector of the second or third embodiments, wherein the metal enclosure is directly attached to the PCB via screws, thereby connecting the sense elements to an electronic circuit of the PCB.

A fifth embodiment may include the explosion proof ultrasonic detector of any of the first to fourth embodiments, wherein the sense element comprises a piezoelectric sense element.

A sixth embodiment may include the explosion proof ultrasonic detector of any of the first to fifth embodiments, wherein the compression element provides explosion protection to the sense element, and the other elements of the detector.

A seventh embodiment may include the explosion proof ultrasonic detector of any of the first to sixth embodiments, wherein, when the detector is assembled, the sense element is under compression between the metal enclosure (and solder) and the PCB, via the compression element.

An eighth embodiment may include the explosion proof ultrasonic detector of the seventh embodiment, wherein the compression reduces the risk of separation between the sense element and the electrodes and/or, which could occur due to strong mechanical shock, vibration, thermal shock, and/or excessive piezo resonance.

A ninth embodiment may include the explosion proof ultrasonic detector of any of the first to eighth embodiments, wherein the surface of the metal enclosure attached to the sense element functions as a membrane to transfer sound pressure waves from the external environment to the sense element.

A tenth embodiment may include the explosion proof ultrasonic detector of any of the first to ninth embodiments, further comprising an instrument enclosure sealed to the metal enclosure.

An eleventh embodiment may include the explosion proof ultrasonic detector of the tenth embodiment, further comprising a sealing material between the metal enclosure and the instrument enclosure, wherein the sealing material provides isolation between the instrument enclosure and the metal enclosure, thereby protecting the sense element, the compression element, and the PCB.

A twelfth embodiment may include the explosion proof ultrasonic detector of the tenth or eleventh embodiments, further comprising a locking ring configured to hold the metal enclosure within the interior of the instrument enclosure.

A thirteenth embodiment may include the explosion proof ultrasonic detector of any of the tenth to twelfth embodiments, wherein the metal enclosure is separated from the interior of the instrument enclosure via a layer of sealant.

A fourteenth embodiment may include the explosion proof ultrasonic detector of any of the first to thirteenth embodiments, wherein the sense element operates in a Faraday's cage, being surrounded by metal surfaces via the metal enclosure and PCB.

A fifteenth embodiment may include the explosion proof ultrasonic detector of any of the first to fourteenth embodiments, wherein the PCB comprises a continuous metal layer contacting the metal enclosure.

A sixteenth embodiment may include the explosion proof ultrasonic detector of any of the first to fifteenth embodiments, further comprising a coating located on the outward facing surface of the metal enclosure, wherein the coating is configured to allow ultrasound waves to pass through to the metal enclosure.

A seventeenth embodiment may include the explosion proof ultrasonic detector of any of the first to sixteenth embodiments, wherein the detector is configured to survive at least 600 psi pressure from the outside toward the detector and/or from the interior of an instrument toward the detector.

An eighteenth embodiment may include the explosion proof ultrasonic detector of any of the first to seventeenth embodiments, wherein the solder comprises a melting temperature lower than the Curie temperature of the material of the sense element.

In a nineteenth embodiment, a method for assembling an explosion proof ultrasonic detector may comprise soldering a first surface of a sense element to an inner surface of a metal enclosure; applying compression to a second surface of the sense element, wherein the second surface is opposite the first surface; maintaining the compression to the second surface of the sense element via a compression element; and attaching a printed circuit board to the metal enclosure, wherein the printed circuit board contacts the compression element.

A twentieth embodiment may include the method of the nineteenth embodiment, further comprising applying a coating to at least a portion of the outer surface of the metal enclosure.

A twenty-first embodiment may include the method of the nineteenth or twentieth embodiments, further comprising sealing at least a portion of an outer surface of the metal enclosure to an instrument enclosure.

A twenty-second embodiment may include the method of the twenty-first embodiment, further comprising attaching a locking ring to the printed circuit board and/or metal enclosure configured to retain the metal enclosure within the instrument enclosure.

A twenty-third embodiment may include the method of the twenty-second embodiment, further comprising attaching a locking ring to the printed circuit board and/or metal enclosure configured to retain the metal enclosure within the instrument enclosure.

While various embodiments in accordance with the principles disclosed herein have been shown and described above, modifications thereof may be made by one skilled in the art without departing from the spirit and the teachings of the disclosure. The embodiments described herein are representative only and are not intended to be limiting. Many variations, combinations, and modifications are possible and are within the scope of the disclosure. Alternative embodiments that result from combining, integrating, and/or omitting features of the embodiment(s) are also within the scope of the disclosure. Accordingly, the scope of protection is not limited by the description set out above, but is defined by the claims which follow, that scope including all equivalents of the subject matter of the claims. Each and every claim is incorporated as further disclosure into the specification and the claims are embodiment(s) of the present invention(s). Furthermore, any advantages and features described above may relate to specific embodiments, but shall not limit the application of such issued claims to processes and structures accomplishing any or all of the above advantages or having any or all of the above features.

Additionally, the section headings used herein are provided for consistency with the suggestions under 37 C.F.R. 1.77 or to otherwise provide organizational cues. These headings shall not limit or characterize the invention(s) set out in any claims that may issue from this disclosure. Specifically and by way of example, although the headings might refer to a “Field,” the claims should not be limited by the language chosen under this heading to describe the so-called field. Further, a description of a technology in the “Background” is not to be construed as an admission that certain technology is prior art to any invention(s) in this disclosure. Neither is the “Summary” to be considered as a limiting characterization of the invention(s) set forth in issued claims. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of the claims shall be considered on their own merits in light of this disclosure, but should not be constrained by the headings set forth herein.

Use of broader terms such as “comprises,” “includes,” and “having” should be understood to provide support for narrower terms such as “consisting of,” “consisting essentially of,” and “comprised substantially of.” Use of the terms “optionally,” “may,” “might,” “possibly,” and the like with respect to any element of an embodiment means that the element is not required, or alternatively, the element is required, both alternatives being within the scope of the embodiment(s). Also, references to examples are merely provided for illustrative purposes, and are not intended to be exclusive.

While several embodiments have been provided in the present disclosure, it should be understood that the disclosed systems and methods may be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted or not implemented.

Also, techniques, systems, subsystems, and methods described and illustrated in the various embodiments as discrete or separate may be combined or integrated with other systems, modules, techniques, or methods without departing from the scope of the present disclosure. Other items shown or discussed as directly coupled or communicating with each other may be indirectly coupled or communicating through some interface, device, or intermediate component, whether electrically, mechanically, or otherwise. Other examples of changes, substitutions, and alterations are ascertainable by one skilled in the art and could be made without departing from the spirit and scope disclosed herein.

What is claimed is:

1. An explosion proof ultrasonic detector comprising:
a metal enclosure configured to face ultrasound pressure waves;
a sense element, wherein the sense element is attached to the metal enclosure via solder;
a compression element configured to contact the sense element; and
a printed circuit board configured to compress the compression element and to connect electrically to the sense element.

2. The explosion proof ultrasonic detector of claim 1, wherein the sense element comprises one or more electrodes.

3. The explosion proof ultrasonic detector of claim 2, wherein the metal enclosure functions as an electrode of the sense element.

4. The explosion proof ultrasonic detector of claim 3, wherein the metal enclosure is directly attached to the printed circuit board via screws, thereby connecting the sense elements to an electronic circuit of the printed circuit board.

5. The explosion proof ultrasonic detector of claim 1, wherein the sense element comprises a piezoelectric sense element.

6. The explosion proof ultrasonic detector of claim 1, wherein the compression element provides explosion protection to the sense element.

7. The explosion proof ultrasonic detector of claim 1, wherein, when the detector is assembled, the sense element is under compression between the metal enclosure (and solder) and the PCB, via the compression element.

8. The explosion proof ultrasonic detector of claim 7, wherein the compression reduces the risk of separation between the sense element and the electrodes in response to a strong mechanical shock, vibration, thermal shock, and/or excessive piezo resonance.

9. The explosion proof ultrasonic detector of claim 1, further comprising an instrument enclosure sealed to the metal enclosure.

10. The explosion proof ultrasonic detector of claim 9, further comprising a sealing material between the metal enclosure and the instrument enclosure, wherein the sealing material provides isolation between the instrument enclosure and the metal enclosure, thereby protecting the sense element, the compression element, and the printed circuit board.

11. The explosion proof ultrasonic detector of claim 9, further comprising a locking ring configured to hold the metal enclosure within the interior of the instrument enclosure.

12. The explosion proof ultrasonic detector of claim 1, wherein the printed circuit board comprises a continuous metal layer contacting the metal enclosure.

13. The explosion proof ultrasonic detector of claim 1, further comprising a coating located on the outward facing surface of the metal enclosure, wherein the coating is configured to allow ultrasound waves to pass through to the metal enclosure.

14. The explosion proof ultrasonic detector of claim 1, wherein the detector is configured to survive at least 600 psi pressure from the outside toward the detector and/or from the interior of the ultrasonic detector outwards.

15. The explosion proof ultrasonic detector of claim 1, wherein the solder has a melting temperature lower than a Curie temperature of the material of the sense element.

16. A method for assembling an explosion proof ultrasonic detector, the method comprising:
soldering a first surface of a sense element to an inner surface of a metal enclosure;
applying compression to a second surface of the sense element, wherein the second surface is opposite the first surface;
maintaining the compression to the second surface of the sense element via a compression element; and
attaching a printed circuit board to the metal enclosure, wherein the printed circuit board contacts the compression element.

17. The method of claim 16, further comprising applying a coating to at least a portion of the outer surface of the metal enclosure.

18. The method of claim 16, further comprising sealing at least a portion of an outer surface of the metal enclosure to an instrument enclosure.

19. The method of claim 18, further comprising attaching a locking ring to the printed circuit board and/or metal enclosure configured to retain the metal enclosure within the instrument enclosure.

20. The method of claim 16, wherein soldering heats the sense element to a temperature lower than a Curie temperature of the material of the sense element.
